(19) United States
(12) Patent Application Publication
(10) Pub. No.: US 2011/0146065 A1
(43) Pub. Date: Jun. 23, 2011

(54) CLEANING DEVICE OF BOARD AND CLEANING METHOD, FLAT DISPLAY PANEL, MOUNTING EQUIPMENT OF ELECTRONIC PARTS AND MOUNTING METHOD

(76) Inventors: Katsunori NAGATA, Yamatokoriyama-shi (JP); Masaya Arimoto, Tenri-shi (JP)

(21) Appl. No.: 13/015,620

(22) Filed: Jan. 28, 2011

Related U.S. Application Data
(62) Division of application No. 10/588,753, filed on Dec. 20, 2006, now abandoned.

(30) Foreign Application Priority Data
Feb. 10, 2004 (JP) 2004-033613
Feb. 10, 2004 (JP) 2004-033614

(51) Int. Cl. H05K 13/04

(52) U.S. Cl. 29/729

(57) ABSTRACT

A mounting apparatus for mounting electronic parts includes, a part conveying device in which a plurality of part holding portions are integrally provided, along a peripheral direction at a predetermined interval, wherein the plurality of part holding portions are intermittently driven in a peripheral direction; a part supply portion for supplying an electronic part to each part holding portion of the part conveying device intermittently driven; and an inspection device for inspecting whether or not dust is attached to the electronic parts supplied and held by the part holding portion at a position where the part holding portion stops due to the intermittent driving of the part conveying device.

### CROSS REFERENCE TO RELATED APPLICATION

This application is a Divisional of co-pending application Ser. No. 10/588,753 filed on Dec. 20, 2006, and for which priority is claimed under 35 U.S.C. §120. The co-pending application Ser. No. 10/588,753 is a national stage application of PCT/JP2005/002189, filed Feb. 8, 2005. This application also claims priority of Application No. 2004-033613 filed in Japan on Feb. 10, 2004, and Application No. 2004-033614 filed in Japan on Feb. 10, 2004 under 35 U.S.C. §119. The entire contents of all of the above applications are hereby incorporated by reference.

### TECHNICAL FIELD

The present invention relates to a cleaning device and a cleaning method for cleaning the edge portion of a board in which terminals are formed, such as a flat display panel, and mounting equipment of electronic parts in which the mounting equipment mounts the electronic parts after cleaning the edge portion of the board in which terminals are formed, and a mounting method for the electronic parts thereof.

### BACKGROUND

In recent years for example, a board such as a liquid crystal cell has been developed. The liquid crystal cell ordinarily has a rectangular shaped planar surface, and one or more sides of the board's edge portions are formed with a plurality of terminals located at relatively narrow pitches, for example, at intervals on the order of μm units. This edge portion, in which the terminals of the liquid cell are formed, is mounted with a TCP (Tape Carrier Package), which is an electronic component, through a tape-shaped anisotropic conductive material used as a bonding material.

The liquid crystal cell is configured such that two sheets of glass plate are fastened together through a seal member at a predetermined interval. A liquid crystal is sealed between these glass plates. At the same time, the external surface of each glass plate is attached to a deflecting plate. The liquid crystal cell thus constituted is pressure-contacted with anisotropic conductive material on the upper surface of the edge portion, in which terminals are formed. The TCP is initially temporarily pressure-contacted on this anisotropic conductive material, a more permanent pressure-contacting method is then performed.

However, in a case where the edge portion of the liquid crystal cell is pressure-contacted with the TCP, the edge portion, in which the terminals of the liquid crystal cell are formed and the terminal portion of the TCP are attached, maybe contaminated with dust. Because of the dust, a situation may arise where an insulation failure is brought about between adjacent terminals and between the terminals and the TCP.

Hence, when the TCP is mounted on the liquid crystal cell, as shown by Patent Document 1, cleaning is performed in order to eliminate the dust from the edge portion, in which the terminals of the board are formed, and from the terminal portion of the TCP.

In the case of the liquid crystal cell, a liquid crystal cell dust inspection device having a CCD camera inspects whether or not an excessive amount of dust is attached to the cell. When excessive dust is found, high-pressure air blowing is performed in order to remove the dust.

Excessive dust, located on the terminals of a TCP in an intermittent rotation type conveying device having four arms, is cleaned off in the following way. The TCP is initially delivered to an arm at a first stopping position. The TCP held by the arm is rotated by 90 degrees through a second stopping position. The TCP is further rotated by 90 degrees to a third position in which the terminals of the TCP are cleaned by a rolling brush.

Subsequently, the TCP moves to a fourth stopping position by rotating another 90 degrees from the third position. A CCD camera inspects whether or not excessive dust is still attached to the terminal portion of the TCP. When an excessive amount of dust is no longer attached, the TCP is temporarily pressure-contacted with the edge portion of the liquid crystal cell at the fourth position. If, by any chance, an inappropriate amount of dust is still attached to the terminals of the TCP, the operation is repeated such that the arm holding the TCP is returned to the third stopping position and is cleaned again by the rolling brush. After which, the TCP is conveyed again to the fourth position to repeat the inspection and then potentially be temporary pressure-contacted with the edge portion of liquid crystal cell.
[Patent Document 1] Japanese Patent Laid-Open Publication No. 9-153526

According to the method disclosed in the Patent Document 1, in the case of cleaning the liquid crystal cell, the portion where the dust is attached is cleaned by only performing high-pressure air blowing. Hence, the dust can be removed in a situation where the adhering force of the dust attached to the terminal portion of the liquid crystal cell is weak. However, when the adhering force between the dust and the terminal portion of the liquid crystal cell is relatively strong, the dust cannot be removed by simply using the air blowing method. Therefore, the situation may arise where an insulation failure is brought about due to the remaining dust not removed by the air blowing method.

In addition, according to the method disclosed in Patent Document 1, a CCD camera conducts an inspection as to whether or not an excessive amount of dust is attached to the terminal portion of the TCP. The inspection occurs while the TCP further rotates 90 degrees from the third stopping position and moves to the fourth position.

Since the CCD camera conducts imaging while the TCP is moving, a CCD camera is required having advanced and sophisticated features in order to reliably image the TCP during its movement. The situation may arise where not only the cost becomes excessive, but an increased occurrence of imaging-failure is also brought about due to the complexity of the inspection system.

A rolling brush conventionally performs the cleaning of the TCP. However, in order to remove contaminating dust from the terminal portion of the TCP, simply brushing that portion of the TCP by the rolling brush cannot reliably remove the dust due at least in part to the static electricity generated by the friction resulting from the brushing action. More specifically, even if the brush can temporarily remove the dust, the removed dust is reattached to the terminal or to the brush due to the static electricity. After which, the dust may end up being spread back to the terminal.

Moreover, when the TCP, cleaned by the rolling brush, moves from the third stopping position to the fourth stopping position, if a sufficient amount of dust is detected as not being reliably removed, the brushing operation is repeated. The conveying device is reversed and the arm holding the TCP is returned to the third stopping position. At the third stopping position, the rolling brush performs the cleaning again. Then, the TCP is reconveyed to the fourth stopping position.

Hence, in a case where the dust attached to the terminal portion of the TCP is difficult to remove, the conveying device is reversed so as to repeatedly perform the cleaning by a rolling brush until the TCP is sufficiently clear. Therefore, the cycle time required for mounting the TCP becomes longer. In addition, not only is a deterioration of productivity brought about, but also there is the possibility of damaging the TCP due to repeated brushing by the rolling brush.

Thus, there is a need in the art for a cleaning device of a board and a cleaning method that can rapidly and reliably remove the excessive contaminating dust from the terminal portion of the board in which electronic parts are to be mounted.

Further, based on the problems illustrated above, there is a need in the art for mounting equipment of electronic parts capable of reliably and rapidly mounting electronic parts in which excessive dust is not attached to the board.

In addition, there is a need in the art for a method of mounting electronic parts that reliably removes the contaminating dust from a portion in which terminals of the board are formed when the electronic parts are mounted on the board.

Further, there is a need in the art for mounting equipment of electronic parts in which the dust can be rapidly and reliably removed from the electronic parts mounted on a board.

### SUMMARY

The cleaning device of the present invention comprises a static brush that brushes the edge portion of the board and removes dust that attaches to and contaminates the edge portion. According to the invention, since the brush for brushing the edge portion (i.e., the portion in which terminals are formed) of the board is a stationary brush, dust attached to the board can be removed without damaging the terminals of the board side. Moreover, the removed dust can be prevented from flying around and adhering to the board again. The present invention may include a brush that brushes the edge portion of the board and removes excessive dust attached to this edge portion, an ion injection device for injecting ionized gas towards a portion to at least contact the edge portion of the board and the brush, and a discharge device capable of absorbing and removing the gas injected toward the brush from the ion injection device. By not only brushing the edge portion (i.e., the portion in which terminals are formed) of the board with a brush, but also by injecting an ionized gas towards that portion, potential build up of static electricity, generated through the brushing by the brush, is removed or diminished. Therefore, contaminating dust attached or solidly fixed to the edge portion of the board can be reliably removed. Further, by removing or reducing the static electricity, even when there would have been a possibility that a static electric discharge could have occured on the board, such a static electric breakdown can be prevented.

Further, part mounting equipment, according to the present invention mounts, electronic parts on an edge portion of the board in which terminals are formed, a part conveying device in which a plurality of part holding portions are integrally provided along a peripheral direction at a predetermined interval and these part holding portions are intermittently driven in a peripheral direction, a part supplying portion for supplying electronic parts successively to each part holding portion of the part conveying device intermittently driven, and an inspection device for inspecting whether or not an excessive amount of contaminating dust is attached to the electronic parts supplied and held by the part holding portion. The inspection occurs at a position where said part holding portion stops due to the intermittent driving of the part conveying device. Since the inspection as to whether or not an excessive amount of dust is attached to the electronic parts is performed at a position in which the conveyance of the electronic parts has stopped, the inspection can be reliably performed with a relatively low cost device.

### BRIEF DESCRIPTION OF THE DRAWINGS

FIG. 1 is an oblique view showing a general structure of a liquid crystal cell;

FIG. 2 is a block diagram showing a general production process of mounting equipment of the present invention;

FIG. 3 is a sectional view along a longitudinal direction of a cleaning device for cleaning an edge portion of an upper surface of a liquid crystal cell;

FIG. 4 is a sectional view along a width direction of the cleaning device;

FIG. 5 is an explanatory drawing showing a step of cleaning successively one side of the liquid crystal cell, and a side adjacent to this one side;

FIG. 6 is a top view showing the mounting equipment of the TCP;

FIG. 7 is an oblique view showing a general structure of the mounting equipment;

FIG. 8 is a side sectional view showing an outline of a terminal cleaning portion according to the present invention;

FIG. 9 is a front sectional view of a jig and a terminal cleaning portion;

FIG. 10 is an enlarged oblique view of a nozzle member and a brush;

FIG. 11 is an oblique view showing the outline of a temporary pressure contacting portion according the present invention;

FIG. 12 is a front sectional view showing a part holding portion in a state disposed at a retreat position;

FIG. 13 is a front sectional view showing the part holding portion in a state disposed at a cleaning position;

FIG. 14 is a side sectional view showing the part holding portion in a state disposed at a cleaning position;

FIG. 15 is a front sectional view of the jig and cleaning device; and

FIG. 16 is a side sectional view of the cleaning device.

### DETAILED DESCRIPTION OF THE PRESENT INVENTION

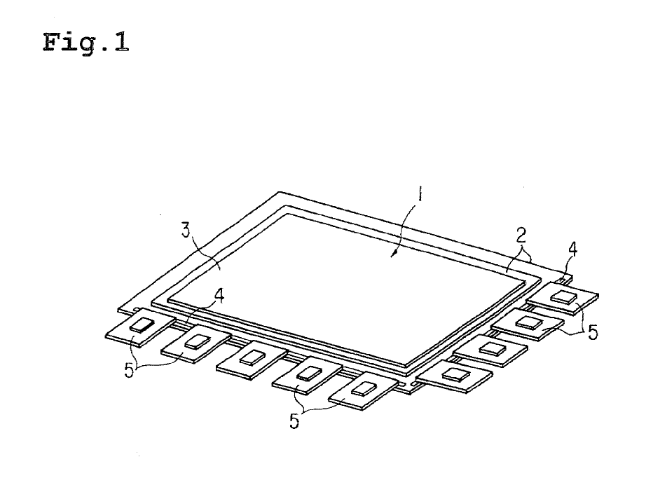

FIG. 1 shows a liquid crystal cell 1 as a board assembled by the mounting equipment of the present invention. This liquid crystal cell 1 is constituted such that a pair of glass boards 2 is fastened together through a seal member (not shown) at a predetermined interval, and a liquid crystal is filled between these glass boards. In addition, the external surface of each glass board 2 is respectively attached to a deflecting plate 3 (only one side is shown) across the whole surface except for a peripheral edge portion. Two sides of the edge portion upper surface of the lower side glass board 2 are formed with a plurality of terminals (not shown) at intervals on the order of μm unit. To this edge portion, a tape-shaped anisotropic conductive material 4 is attached. This anisotropic conductive material 4 is mounted to the TCP 5's, which are formed with a plurality of terminals (not shown) as the electronic parts at intervals of μm unit, while the TCP 5's have their terminal portions adhered to the anisotropic conductive material 4.

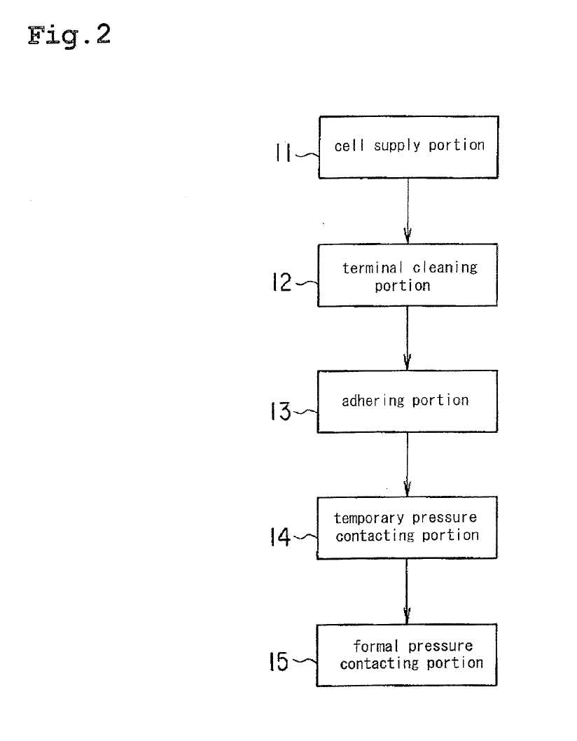

FIG. 2 is a block diagram showing a general structure of the mounting equipment for assembling the liquid crystal cell 1. This mounting equipment has a cell supply portion 11 for supplying the liquid crystal cell 1 to be mounted with the TCP 5's. From this cell supply portion 11, the liquid crystal cell 1 is supplied to a terminal cleaning portion 12. In the terminal cleaning portion 12, as will be described in more detail later, contaminating dust attached to the edge portion upper surfaces of two adjacent sides, in which the terminals of the crystal cell 1 are formed, is removed.

The liquid crystal cell 1, in which the dust is removed from the edge upper surfaces of the two adjacent sides by the cell cleaning portion 12, is supplied to an adhering portion 13 of the anisotropic conductive material 4. Here, the tape-shaped anisotropic conductive material 4 is respectively attached to the edge upper surfaces of the two sides of the liquid crystal cell 1 along a longitudinal direction. The two sides attached with the anisotropic conductive material 4 of the liquid crystal cell 1 are pressure-contacted with the TCP 5's by a temporary pressure-contacting portion 14, also to be described later. Then, in a formal pressure-contacting portion 15, a formal or more permanent pressure-contacting is conducted in which the heating and hardening of the anisotropic conductive material 4 is performed.

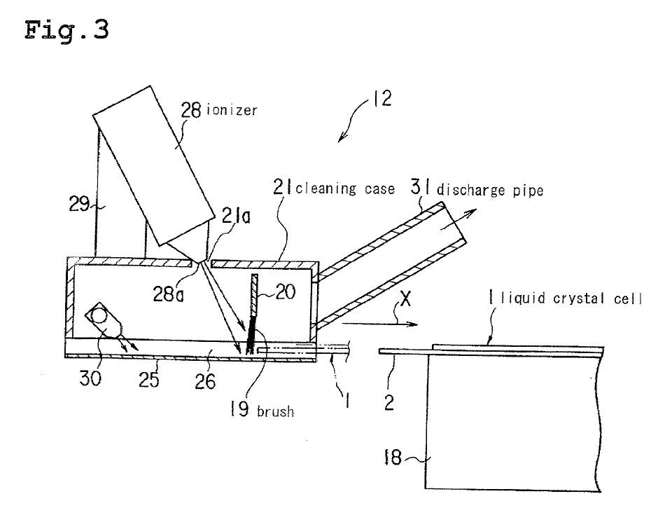

As shown in FIG. 3, the terminal cleaning portion 12 comprises a conveying table 18 mounted with the liquid crystal cell 1. The conveying table 18 is driven in a 8 direction of rotation. An X direction and a Y direction are orthogonal to each other on a horizontal surface perpendicular to the plane of FIG. 3. An axial line orthogonal to the horizontal surface is not shown but would act as a center. A brush 19 cleans the edge portion of the upper surface of the two sides of the liquid crystal cell 1, later mounted with the TCP 5's. The liquid crystal cell 1 is supplied and held on the upper surface of the conveying table 18. The two sides of the liquid crystal cell 1, to be mounted with the TCP 5's, protrude to the outside of the side edge of the conveying table 18.

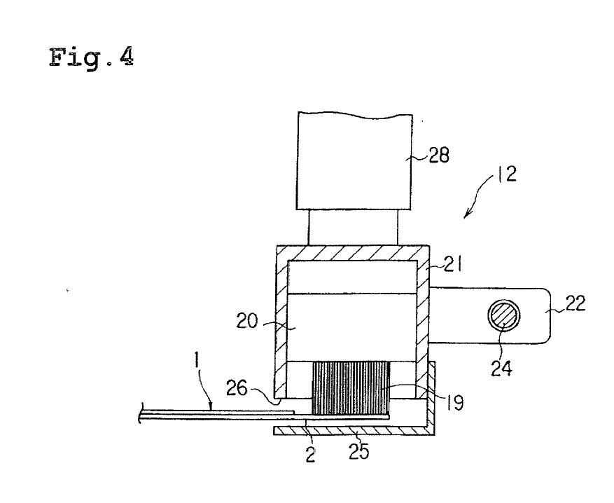

The cleaning brush 19 is fixed to a mounting member 20. The mounting member 20 is provided across the width direction at one end (in regards to a longitudinal direction) inside of a box type cleaning case 21, the undersurface of which is opened. The lower end portion of the brush protrudes downward from the undersurface opening of the cleaning case 21. More specifically, the brush 19 is a stationary brush (i.e., fixed brush), which in this configuration is neither rotated nor driven. The width size of the brush 19, as shown in FIG. 4, is designed in such a way as to be able to brush the whole portion of the edge portion upper surface of the liquid crystal cell 1 to be attached with the anisotropic conductive member 4, or a brush 19 with a width size larger than the portion to be attached with the anisotropic conductive member 4.

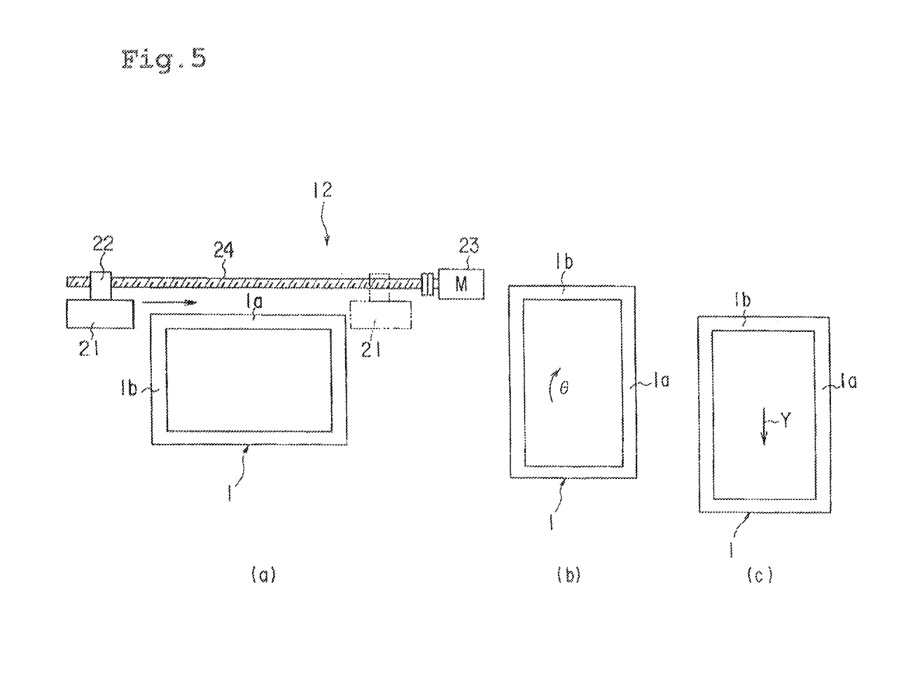

As shown in FIGS. 4 and 5, one side surface of the cleaning case 21 is provided with a female screw unit 22. The female screw unit 22 is threadably interfaced with a ball screw shaft 24, which is rotated and driven in a reciprocal direction by a motor 23. The female screw unit 22 allows the ball screw shaft 24 to rotate, while remaining un-rotated with respect to the motor 23 driving the ball screw shaft 24. A guide (not shown) and the like hold the female screw unit 22 in an un-rotated configuration. Moreover, the female screw unit 22 is movable in an axial direction of the ball screw shaft 24. In this way, when the ball screw shaft 24 is rotated and driven by the motor 23, the cleaning case 21 is driven along the shaft line direction of the ball screw shaft 24.

As shown in FIGS. 3 and 4, the undersurface of the cleaning case 21 is integrally provided with a plate type of receiving member 25. The receiving member 25 forms a predetermined gap 26 with the undersurface of the cleaning case 21. That is, one end side of the receiving member 25 is substantially configured in the shape of the letter L with regard to a width direction, and fixed at an external surface of the cleaning case 21. The remaining three sides are opened to the undersurface of the cleaning case 21.

In a state in which an edge portion of the liquid crystal cell 1 is protruding from the side edge of the conveying table 18, and the edge portion of the liquid crystal cell 1 is inserted into the gap 26 at the undersurface of the cleaning case 21 formed by the receiving member 25, the cleaning case 21 is driven by the ball screw shaft 24 along that edge portion. In this way, the edge portion of the liquid crystal cell 1 is brushed and cleaned by the brush 19 provided in the interior of the cleaning case 21. Since the brush 19 is a stationary brush and not a rolling brush, the potential damage to the liquid crystal cell 1 from being brushed by the brush 19, particularly the potential damage to the terminals provided in the liquid crystal cell 1, can be reduced. Moreover, because the brush 19 is a stationary brush, dust removed by brush 19 can be more controlled so as to not fly around the brush 19 in all directions.

The upper external surface of the cleaning case 21 is provided with an ionizer 28 for use as an ion injection device. The ionizer 28 is inclined at a predetermined angle by a holding member 29. The top end portion of this ionizer 28 (located near the cleaning case 21 in FIG. 3) serves as an injection orifice 28a. The injection orifice 28a is located opposed to an opened hole 21a formed in an upper wall of the cleaning case 21. The injection orifice 28a is directed at the top end portion of the brush 19 (i.e., located at the end of the brush opposite to the end attached to the mount 20) fixed in the interior of the cleaning case 21. The injecting direction of the air by the ionizer 28, as shown in FIG. 3, is set in reverse (i.e., opposing) to the relative ingress direction of the glass board 2 of the liquid crystal cell 1 as the liquid crystal cell 1 moves toward the terminal cleaning portion 12.

The ionizer 28 is supplied with compressed air by a supply tube (not shown). The ionizer 28 ionizes the compressed air supplied to the ionizer 28. The ionized air is then injected from the injection orifice 28a at the top end of the ionizer 28 towards the top end portion of the brush 19. In this way, even when the brush 19 brushes the edge portion of the liquid crystal cell 1, the ionized compressed air helps to prevent the generation of a static electric charge.

The other end portion (i.e., in regards to a longitudinal direction) of the interior of the cleaning case 21 is provided with a nozzle member 30 that injects compressed air towards the direction of the brush 19. Further, one end portion of the cleaning case 21 is connected to a discharge duct 31, which constitutes a discharge device together with the cleaning case 21. This discharge duct 31 is connected to a vacuum pump (not shown), by which the atmosphere in the interior of the cleaning case 21 is drawn through the discharge duct 31. Further, the injecting direction of the air from the nozzle member 30, as shown in FIG. 3, is set in a direction reverse to the ingress direction of the glass board 2 of the liquid crystal cell 1.

In a state in which the edge portion of the liquid crystal cell 1 ingresses (i.e., enters) into the gap 26 of the undersurface of the cleaning case 21, the cleaning case 21 is driven in a direction shown by an arrow X in FIG. 3. This results in the edge portion upper surface of the liquid crystal cell 1 being brushed and cleaned by the brush 19. At this time, a portion of the dust, brushed away from the edge portion upper surface of the liquid crystal cell 1, is discharged through the discharge duct 31 together with the atmosphere in the interior of the cleaning case 21. A remaining portion of the dust falls upon the upper surface of the receiving member 25. The dust fallen on the upper surface of the receiving member 25 is subsequently blown away towards the discharge duct 31 due to the compressed air injected from the nozzle member 30. Therefore, the remaining dust is drawn into this discharge duct 31 and discharged.

In this way, the nozzle member 30, injecting still further high pressure gas, is provided separately from the ionizer 28. This allows the dust removed from the glass board 2 to be reliably discharged without requiring an increase in the injection pressure of the air supplied by the ionizer 28. Therefore, the generating capacity of the ionized air from the ionizer 28 can be prevented from being reduced. Further, since the injecting direction of the gas from the nozzle member 30 and the ionizer 28 are both set in a direction reverse or opposite to the ingress direction of the glass board 2, a situation in which the dust is blown away and yet adheres again to the glass board 2 can be prevented from occurring.

To clean the adjacent two sides of the liquid crystal cell 1 by the brush 19, the liquid crystal cell 1 is initially positioned by the conveying table 18 so that one side, the side 1a in a longitudinal direction of the liquid crystal cell 1, slots into the gap 26 of the undersurface side of the cleaning case 21. Then, as shown in FIG. 5(a), the cleaning case 21 is driven in an X direction along the one side 1a of the liquid crystal cell 1. The brush 19, as described above, subsequently cleans the one side 1a.

When the cleaning of the one side 1a is completed, as shown in FIG. 5(b), the liquid crystal cell 1 is rotated 90 degrees in a θ direction as shown by the arrow (i.e., clockwise in this embodiment) by the conveying table 18 mounted with the liquid crystal cell 1. In this way, one side 1b in a traverse direction adjacent to the one side 1a in the longitudinal direction of the liquid crystal cell 1 is positioned in parallel with the driving direction of the cleaning case 21.

Subsequently, as shown in FIG. 5(c), the liquid crystal cell 1 is driven by the conveying table 18 in a Y direction, shown by the arrow Y in the drawing, and the short side 1b of the liquid crystal cell 1 is positioned in such a way as to slot into the gap 26 of the undersurface of the cleaning case 21. In this configuration, if the ball screw shaft 24 drives the cleaning case 21 the brush 19 will clean the short side 1b of the liquid crystal cell 1 in a manner similar to the long side 1a.

When the cleaning of two sides of the liquid crystal cell 1, i.e., the long side 1a and the short side 1b which are both to be temporarily pressure-contacted with the TCP 5's, is completed by the terminal cleaning portion 12, the liquid crystal cell 1 has the anisotropic conductive member 4 attached to the two sides by the adhering portion 13.

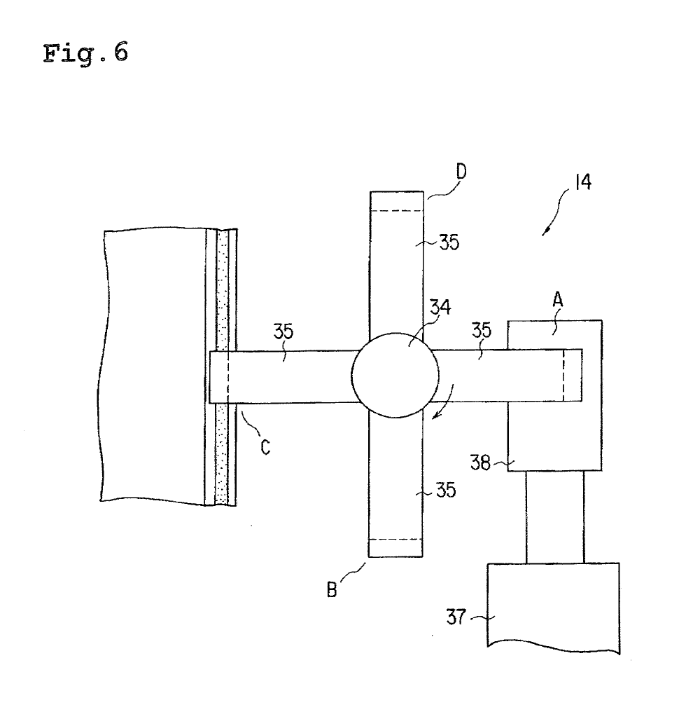

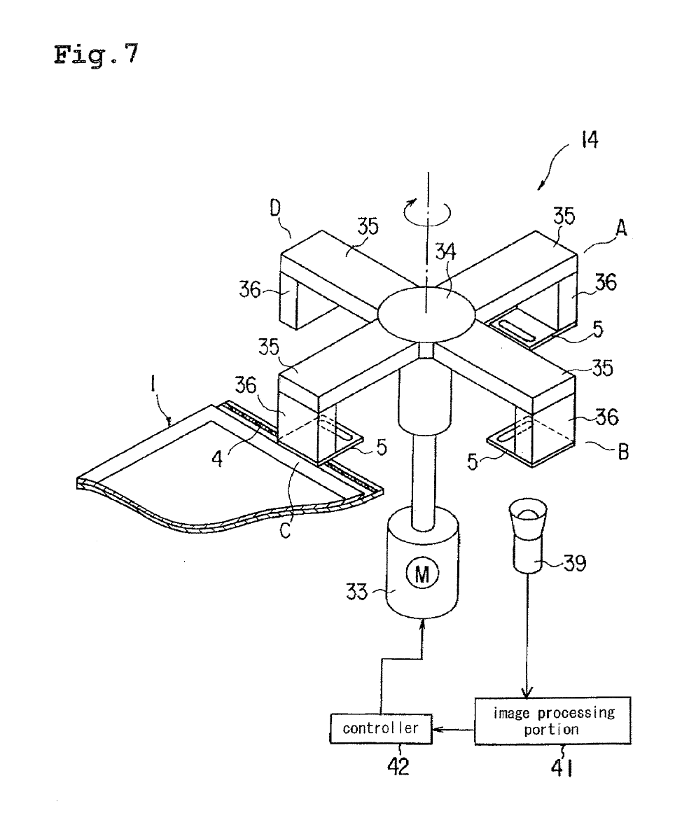

Subsequently, the two sides of the liquid crystal cell 1, temporarily attached with the anisotropic conductive member 4, are temporarily pressure-contacted with the TCP 5's by the temporary pressure contacting portion 14. The temporary pressure contacting portion 14, as shown in FIGS. 6 and 7, comprises a body of rotation 34 which is intermittently rotated and driven in intervals of 90 degrees by a motor 33. The outer peripheral surface of the body of rotation 34 is provided with four individual arms 35 in the peripheral direction also positioned at intervals of 90 degrees. The distal end of each arm 35 is provided with a holding portion 36 that retrieves and holds a TCP 5.

Respective holding portions 36 are provided on the top ends of the four arms 35 (shown as just below the arm portion in FIG. 7). The four aims 35 and their respective holding portions 36 respectively stop for a predetermined period of time at four positions shown by references A to D in FIGS. 6 and 7. The arms 35 and the holding portions 36 are intermittently rotated and driven. At position A, a TCP 5 is punched out from a carrier tape (not shown) by a punching device 37 and supplied by a part supply device 38 to be retrieved and held by a holding portion 36.

At position B, as shown in FIG. 7, the TCP 5, retrieved and held by the holding portion 36, is imaged from below by, for example, a CCD camera 39, which is an imaging device. More specifically, the terminal portion of the TCP 5 to be connected to the liquid crystal cell 1 is imaged. The imaging signal of the CCD camera 39 is outputted to an image processing portion 41. The image processing portion 41 subjects the imaging signal from the CCD camera 39 to binary processing according to its luminance, and determines whether or not contaminating dust of more than a predetermined size is attached to the terminal portion of the TCP 5.

The determination result from the image processing portion 41 is outputted to a controller 42. In the case where the TCP 5 is not attached with contaminating dust of more than a predetermined size, the controller 42, according to the determination result, outputs an instruction to have the TCP 5 temporarily pressure-contacted with the edge portion of the liquid crystal cell 1, cleaned by the terminal cleaning portion 12 and attached with the anisotropic conductive member 4, at position C. As a result, at position C the holding portion 36 that retains and holds the inspected TCP 5 descends and releases the TCP 5. The TCP 5 is then temporarily pressure-contacted to the anisotropic conductive member 4 attached to the edge portion upper surface of the liquid crystal cell 1.

In a situation where contaminating dust of more than a predetermined size is attached to the terminal portion of the TCP 5, the controller 42 does not allow the holding portion 36 to descend at position C based upon the determination result from the image processing portion 41. Instead, the holding portion 36 waits at a location above the position C and remains attached to the inspected TPC 5. Subsequently, when the inspected TCP 5 with the contaminated terminal portion reaches position D, through the further 90-degree rotation of the body of rotation 34, the controller 42 releases the retrieval and holding state of the inspected TCP 5 by the holding portion 36, which is positioned at the position D. In this way, the contaminated TCP 5 attached with dust is discarded at position D.

Since whether or not the dust is attached to the TCP 5 is detected at position B, the discarding of a contaminated TCP 5 may be performed at any time while the holding portion 36 moves from position B to position D, with the possible exception of directly above position C.

In this way, the temporary pressure contacting portion 14 discards the contaminated TCP 5 attached with dust of more than a predetermined size at the position D, and temporarily pressure contacts the next TCP 5, which in this example is not attached with dust, with the liquid crystal cell 1 at position C. Hence, when compared to the conventional case where the removal and inspection of the dust attached to the TCP 5 is repeatedly performed, a cycle time required for the temporary pressure contacting may be shortened, so that an improvement of productivity may be realized.

An imaging inspection as to whether or not contaminating dust is attached to the TCP 5 is performed at position B. That is, in the process of temporarily pressure contacting the TCP 5 with the liquid crystal cell 1 by intermittently driving the four holding portions 36, the CCD camera 39 images the TCP 5 when a holding portion 36 stops. Hence, since the TCP 5 can be imaged during a stopped state and the imaging can be performed without causing defocusing or experiencing other problems associated with trying to image a moving target. Moreover, since the TCP 5 is imaged at a position where it would otherwise stop (i.e., while one of the other arms is temporarily pressure contacting a TCP 5 at position C) there is no need to stop the rotation of the body of rotation 34 purposely for imaging. As a result, no exclusive time for imaging is required, and because of this point also, the cycle time can be a shortened.

A TCP 5 is temporarily pressure contacted at a place, which is attached with the anisotropic conductive member 4, on the liquid crystal cell 1 by the temporary pressure contacting portion 14. The TCP 5 is then formally pressure contacted at the formal pressure contacting portion 15 at a temperature in which the anisotropic conductive member 4 is hardened. In this way, the mounting of the TCP 5 onto the liquid crystal cell 1 is completed.

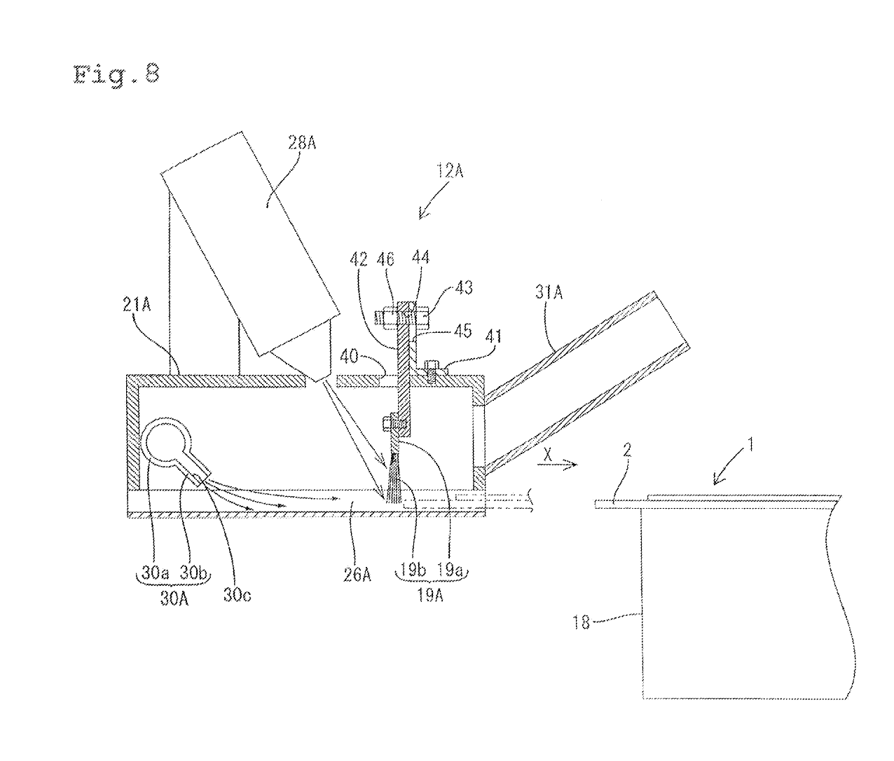

Another aspect of the present invention will be described with reference to FIGS. 8 through 10. In this configuration there is a modification regarding the structure of a terminal cleaning portion 12A, which is the cleaning device of the edge portion of the glass board 2, and a cleaning method is shown for the terminal. In this configuration, a repeated description of the same structure, operation, and effect, as in FIGS. 1 through 7 will be omitted.

The top board of the cleaning case 21A in the terminal cleaning portion 12A, as shown in FIG. 8, is provided with a detachably attachable brush opening portion 40. Above which a brush 19A is detachably attached. The external surface of the top board of the cleaning case 21A is fixed to a brush mounting member 41 that is adjacent to the detachably attachable brush opening portion 40 and is approximately L-letter shaped in a cross-sectional view. The brush 19A comprises a brush main body 19a and plural pieces of brush hair 19b held in the shape of a bundle aligned by the brush main body 19a.

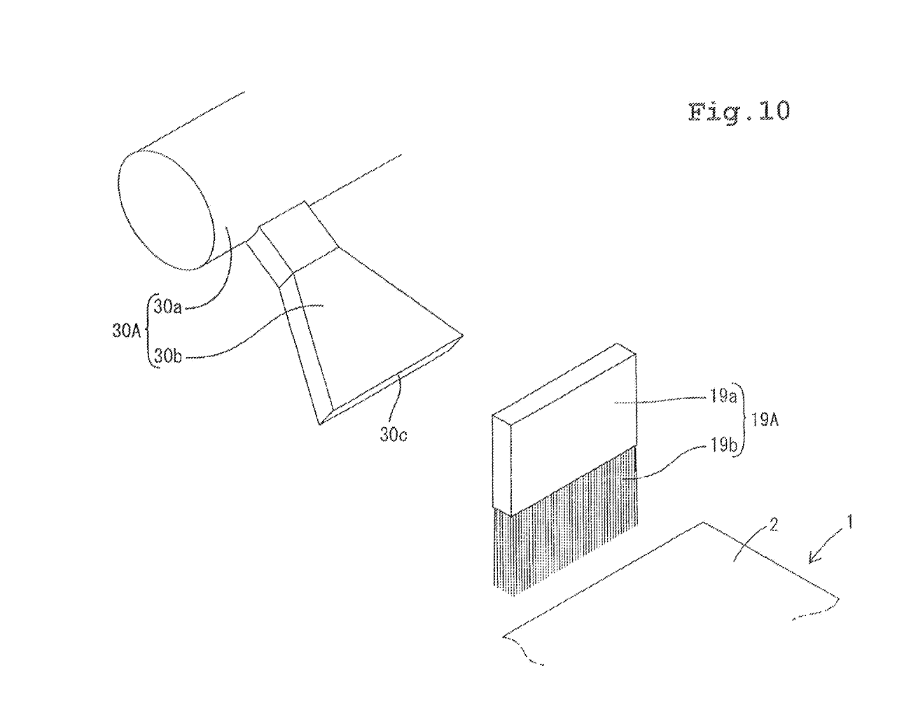

The brush main body 19a, as shown in FIGS. 8 and 10, has a slender oblong shape along the board surface of the glass board 2 of a liquid crystal cell 1. The slender oblong shape of the brush main body 19a is along a direction orthogonal to the relative ingress direction of a glass board 2 as the glass board 2 moves toward the terminal cleaning portion 12A. The brush hair 19b protrudes downward from the undersurface of the brush main body 19a. The protruded top end of the brush hair 19b (i.e., the hair tip at the end opposite to the brush main body 19a) is aligned so as to be in the shape of a flat surface as a whole. This brush hair 19b uses conductive fiber as a raw material. The conductive fiber may be formed by chemically bonding a conductive material such as copper sulfide with a synthetic resin fiber such as acryl fiber, nylon fiber and the like. As a result, even when the brush hair 19b contacts other materials, static electricity is not readily generated. For brush 19A, the end portion of the brush main body 19a, opposite to the brush hair 19b side, is fixed to a flat brush bracket 42. The flat brush bracket 42 is detachably attachable to the brush holding member 41.

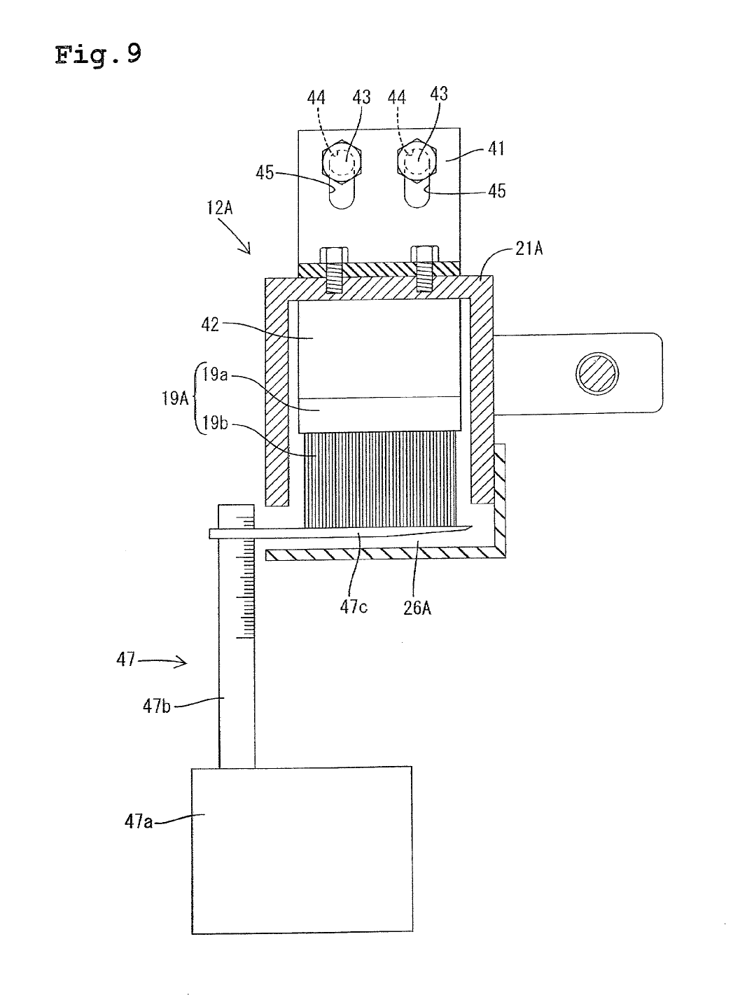

A mounting structure of the brush bracket 42 and the brush holding member 41 will be described next. The brush bracket 42 and the brush holding member 41, as shown in FIGS. 8 and 9, are respectively provided with a pair of insertion holes 44 and 45, and each of the pair of corresponding insertion holes is insertable with a bolt 43. In the configuration in which both of these insertion holes 44 and 45 are mutually matched together, a bolt 43 is inserted into each of these holes and fixed with a nut 46 fastened to the free end of each bolt 43. In this way, the brush 19A can be fixed to the cleaning case 21A in an adjustable mounted state.

Whereas the insertion hole 44 of the brush bracket 42 is circular and has approximately the same diameter as the outer diameter of a bolt 43, the insertion hole 45 of the brush holding member 41 has a slender and long hole (i.e., slot or oval) shape oriented along a vertical direction. Consequently, when the bolts 43 are loosened, the bolts 43 (and corresponding brush bracket 42) can be moved up and down along a longitudinal hole edge of the insertion holes 45 of the brush holding member 41. In this way, the mounting position of the brush 19A can be adjusted up and down (i.e., a direction orthogonal to the board surface of the glass board 2, and a direction that places the brush 19A in and out of contact with the glass board 2). Therefore, the brush bracket 42, brush holding member 41, bolts 43, and the like, constitute the positioning device of the brush 19A.

The nozzle 30A will now be described. The nozzle 30A, as shown in FIGS. 8 and 10, comprises a main body 30a, which has a hollow columnar shape, and a nozzle attachment 30b. The nozzle attachment 30b is attached to the main body 30a at an opening portion provided in the peripheral surface in the vicinity of the end portion of the main body 30a. The end portion of the nozzle attachment 30b, opposite to the end portion connected to the opening portion, is provided with an injection orifice 30c capable of injecting compressed air. This injection orifice 30c is formed in a slender and oblong shape along a long side direction (see FIG. 10, i.e., a direction along the board surface of the glass board 2 and orthogonal to the relative ingress direction of the glass board 2 as the glass board 2 moves toward the terminal cleaning portion 12A) of the brush 19A. The end portion of the main body 30a, opposite to the nozzle attachment 30b side, is connected to a compressed air supply (not shown) for supplying compressed air to the nozzle 30A.

Next, an operation to clean an edge portion will be described, in a longitudinal or traverse direction of the glass board 2, by the terminal cleaning portion 12A constituted as detailed above. When the cleaning case 21A is driven along a direction indicated by the arrow X, shown in FIG. 8 in a state in which the liquid crystal cell 1 is mounted on the conveying table 18, the edge portion of the glass board 2 of the liquid crystal cell 1 enters into the gap 26A at the undersurface of the cleaning case 21A. The relative motion of the liquid crystal cell 1 is in a direction reverse to the direction indicated by the arrow X. The brush hair 19b of the brush 19A then brushes against the edge portion of the glass board 2 so that the dust attached or fixed to the edge portion of the glass board 2, i.e., a terminal forming region of the liquid crystal cell 1, is brushed away. Here, the term “fixed” refers to the case where the dust is connected to the glass board 2 by a force stronger than “adhering”, and for example, it may refer to the case where the dust cannot be reliably removed by the injection of gas alone (i.e., the dust cannot be simply blown away).

At this time, since friction is caused between the brush 19A and the edge portion of the glass board 2, there is a possibility of generating static electricity. However, as described above, since the brush hair 19b includes conductive fiber, the generation of static electricity can be controlled. In addition, since the frictional portion between the brush 19A and the edge portion of the glass board 2 is injected with ionized compressed air by the ionizer 28A, the generation of static electricity due to the friction is controlled or reduced even further. By controlling the generation of static electricity in this way, once the dust is brushed away from the glass board 2, it is difficult for the dust to adhere again to the glass board 2 and the brush 19A. Therefore, a reliable removal of the dust can be performed. Further, as a static electric charge is not readily generated, a static electric breakdown of the liquid crystal cell 1 can be prevented.

During the cleaning, since compressed air, more highly compressed than the ionized gas of the ionizer 28, is injected from the injection orifice 30c of the nozzle body 30A towards the brush 19A and the discharge pipe 31A, dust removed from the glass board 2 is blown away and reliably discharged. Moreover, the injection orifice 30c, as shown in FIG. 10, has an oblong shape oriented along the board surface of the glass board 2. Therefore, the injection orifice 30c can efficiently inject the compressed air to the edge portion of the glass board 2 so that the removed dust can be reliably blown away.

Even after the terminal cleaning portion 12A passes along the edge portion of the glass board 2 and completes the cleaning of the edge portion of the glass board 2, the injection of the compressed air by the nozzle body 30A continues to be performed for a predetermined period of time. As a result, even if by chance some dust is attached to the brush 19A, that attached dust can still be blown away. Therefore, when the other edge portion of the glass board 2 is cleaned or the edge portion of the next (i.e., separate) glass board 2 is cleaned, the cleaning ability of the terminal cleaning portion 12A is prevented from being lowered by contaminating dust attached to the brush 19A.

As the cleaning operation is repeatedly performed as described above, wear and abrasion are inevitably generated in the brush hair 19b. If, due to wear and abrasion, the top end location of the brush hair 19b reaches a location higher than the lower edge of the gap 26A, which is the ingress space of the glass board 2, the cleaning of the glass board 2 by the brush hair 19b becomes impossible. To cope with this situation, in the present embodiment the height position of the brush 19A may be adjusted. A jig 47, used for adjustment of the brush 19A, and an adjusting method will be described below.

This jig 47, as shown in FIG. 9, comprises a ground base 47a, a shaft portion 47b rising from the ground base 47a, and an index portion 47c mounted so as to be vertically movable along the shaft portion 47b. The shaft portion 47b is provided with a scale showing the height position of the index portion 47c. To adjust the position of the brush 19A, the index portion 47c in the jig 47 is initially set to a predetermined height and the index portion 47c is inserted into the gap 26A on the undersurface side of the cleaning case 21A. The height position of the index portion 47c is set to a position that ensures that the brush 19b will reliably contact the edge portion of the glass board 2 when the top end of the brush 19A substantially rests upon the upper surface of the index portion 47c.

If the top end of the brush hair 19b is located at a position higher than the upper surface of the index portion 47c (i.e., a gap exists between the brush 19A and the index portion 47c), the bolts 43 fixing the brush 19A are loosened and the brush 19A is moved downward (i.e., a direction approaching the glass board 2). The bolts 43 move longitudinally along the hole edges of the insertion holes 45 of the brush holding member 41. When the top end of the brush hair 19b visibly reaches a position abutting against the upper surface of the index portion 47c, the bolts 43 are fastened and the brush 19A is fixed in position. The cleaning of the edge portions of the glass board 2 can now be reliably performed. As compared to the case where there is no height adjusting device for the brush 19A nor any alternative but to replace a worn out brush 19A, a relatively longer term usage of a single brush 19A becomes possible, thereby making it possible to realize a lower operating cost.

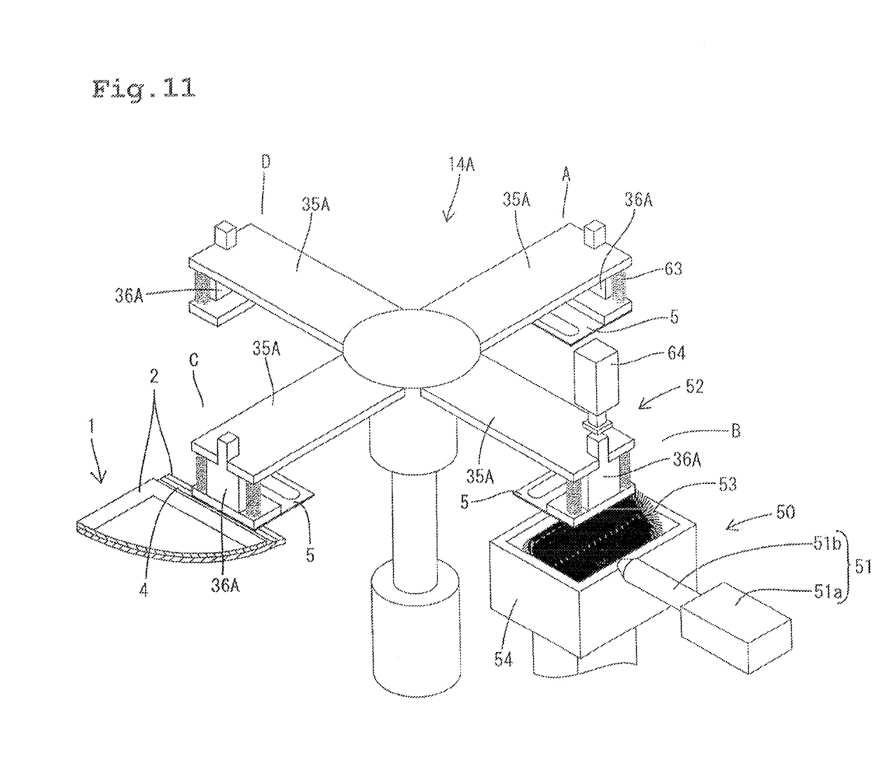

Another aspect of the present invention will be described with reference to FIGS. 11 to 16. In this configuration, with regard to the temporary pressure contacting portion 14A, which is the mounting equipment for a TCP 5, in place of the inspection device (the CCD camera 39, the image processing portion 41, the controller 42, and the like). The temporary pressure contacting portion 14A is provided with a cleaning device 50 and the like, for the cleaning of the terminal forming portion of a TCP 5. In this configuration, a repeated description of the same structure, operation, and the effect, as in FIGS. 1 through 10 will be omitted.

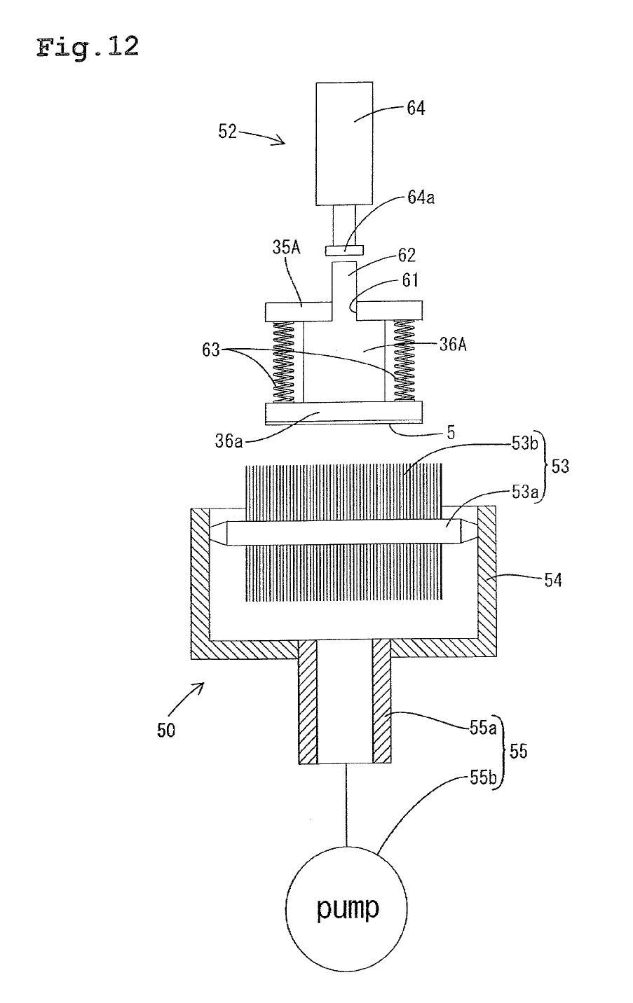

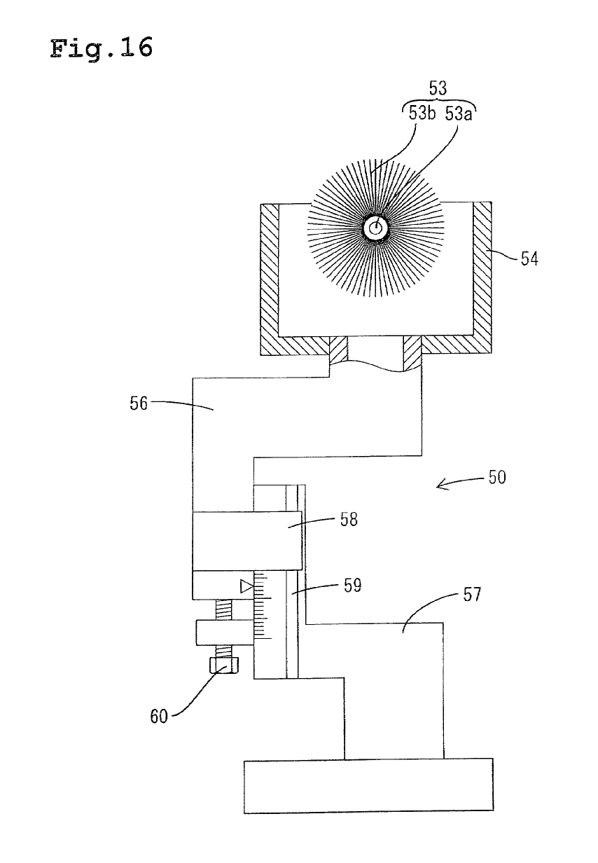

The temporary pressure contacting portion 14A, as shown in FIG. 11, is provided with a cleaning device 50 for cleaning the terminal portion of a TCP 5, an ionizer 51, and an elevating device 52 for allowing a part holding portion 36A to elevate. The part holding portion 36A holds the TCP 5. From among these components, the cleaning device 50 roughly comprises, as shown in FIGS. 12 and 16, a rolling brush 53 for cleaning a terminal forming region (i.e., the connection regions for contacting with the terminals of the liquid crystal cell 1 side) of the TCP 5, a cleaning case 54 to which the rolling brush 53 is attached, a discharge device 55 connected to the cleaning case 54, a support member 56 for supporting the cleaning case 54, and a base portion 57 attached to the support member 56 and provided on the floor surface.

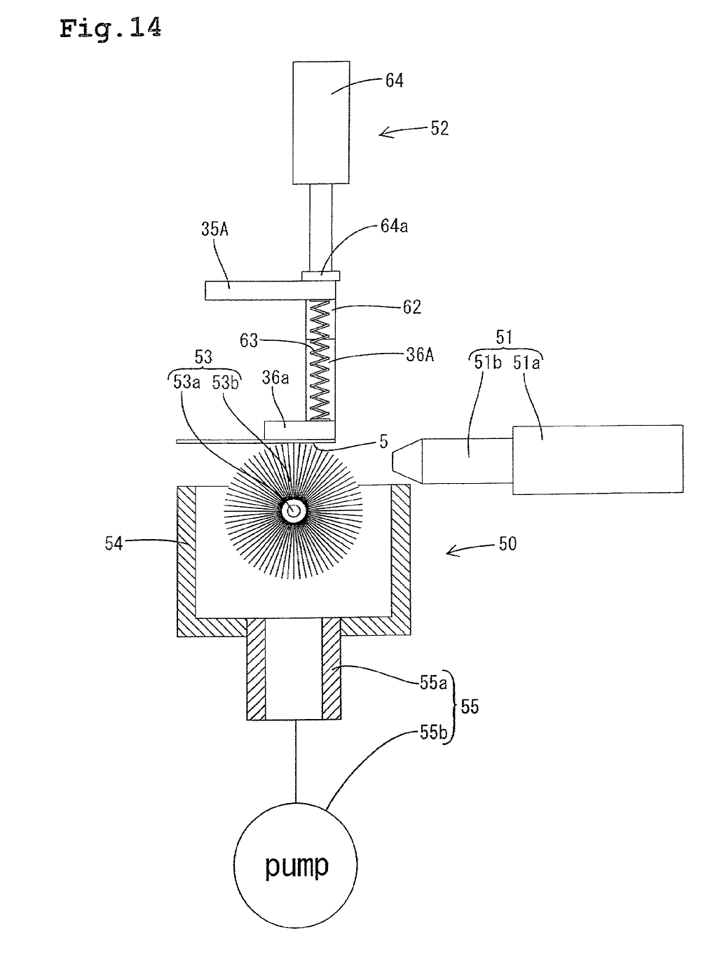

The rolling brush 53, as shown in FIG. 12, comprises a rotating shaft 53a, rotatably attached to the cleaning case 54, and a plurality of brush hair 53b attached to the peripheral surface of the rotating shaft 53a. The rotating shaft 53a is connected to a not illustrated motor. A control device controls the rotation of the not illustrated motor. The brush hair 53b is attached approximately across the entire periphery of the rotating shaft 53a. The top end (i.e., the hair top, the end of the hair opposite to the end attached to the rotating shaft 53a) of the brush hair 53b is cut so as to become substantially circular when seen from the lateral side (see FIG. 14, i.e., approximately forming a cylindrically shaped brush). This brush hair 53b uses a conductive fiber as a raw material. The conductive fiber may be made by chemically bonding a conductive material such as copper sulfide with a synthetic resin fiber such as acryl fiber, nylon fiber, and the like. Consequently, even when the brush hair 53b happens to contact other materials, static electricity is not readily generated.

The cleaning case 54 is formed approximately in the shape of a box, opened upward, so as to enclose the lower portion of the rolling brush 53. The lower side of the cleaning case 54 is provided with a discharge pipe 55a for discharging contaminating dust removed from the TCP 5. The end portion of this discharge pipe 55a is connected to a discharge pump 55b. The discharge pipe 55a and discharge pump 55b constitute a discharge device 55.

The support member 56, as shown in FIG. 16, is attached to the base portion 57 via a slide member 58. This slide member 58 interfaces with a rail portion 59 formed in the base portion 57. The slide member 58 is able to slide with the support member 56 along a vertical direction of the base portion 57. The base portion 57 is connected to a positioning bolt 60 capable of supporting the undersurface of the support member 56 in an upward posture. By operating this positioning bolt 60 so as to advance or retreat the bolt 60, the support member 56 can be vertically moved or adjusted. Corresponding to the vertical movement of the support member 56, the rolling brush 53 also moves in a vertical direction. In other words, the rolling brush 53 may be displaced in a direction in and out of contact with the TCP 5. The positioning device of the rolling brush 53 is constituted by the support member 56, base portion 57, and a positioning bolt 60, and the like. Further, the base portion 57 is provided with a scale corresponding to an eye mark provided on the support member 56 in order to determine the height position of the support member 56.

The ionizer 51, as shown in FIGS. 11 and 14, comprises an approximately box type main body portion 51a and a nozzle portion 51b . The nozzle portion 51b protrudes from the main body portion 51a to a lateral side. The ionized air generated in the interior of the main body portion 51a is injected out from the injection orifice of the nozzle portion 51b in a compressed state by a not illustrated injection device. This nozzle portion 51b is set so as to be directed to a region of contact of the TCP 5 from among the upper portion of the rolling brush 53, i.e., the brush hair 53b.

The elevating device 52 will be described next. The top end portion of the arm 35A, as shown in FIGS. 11 and 12, is formed with a notched guide concave portion 61. The guide concave portion 61 is fitted with the guide convex portion 62 provided on the top end of the part holding portion 36A so that the part holding portion 36A can slide in a vertical direction (i.e., the direction in and out of contact with the rolling brush 53) relative to the arm 35A. From the part holding portions 36A, both side portions of a retrieval portion 36a (for retrieving the TCP 5) and the top end of both side portions of the arm 35A, are connected via a pair of spring members 63. As a result of the spring members 63, the part holding portion 36A is held at a height position in which the held TCP 5 does not contact the rolling brush 53. This position is established as a retreat position (see FIG. 12). When the part holding portion 36A is displaced further downward than this retreat position, the spring members 63 are elastically expanded, thereby causing an elastic restoring force able to restore the part holding portion 36A to the retreat position side.

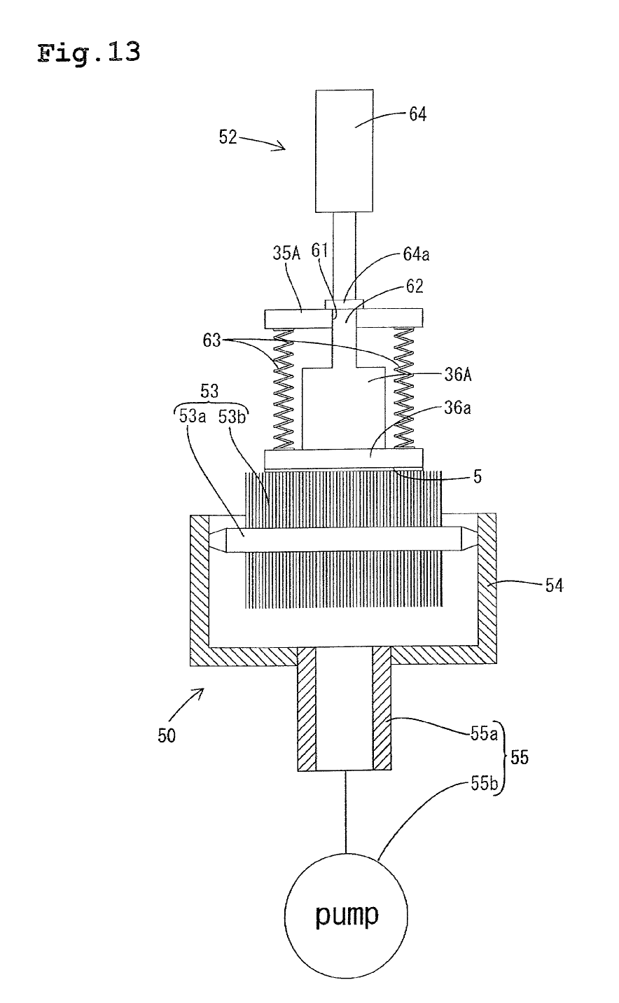

A cylinder 64, disposed above, vertically moves the part holding portion 36A when the part holding portion 36A is in position B, as shown in FIG. 12. In more detail, a piston 64a of the cylinder 64 is disposed at a location vertically opposing the guide convex portion 62 of the part holding portion 36A when the part holding portion 36A is disposed at position B. The piston 64a is driven by a control device (not shown) so as to be vertically movable. The guide convex portion 62 of the part holding portion 36A is pressed down from above by the piston 64a to a predetermined depth. The corresponding part holding portion 36A is consequently displaced downward from the retreat position and the terminal forming portions of the TCP 5 consequently reach a cleaning position (FIGS. 13 and 14) in contact with the rolling brush 53. When the piston 64a is elevated upward and the pressing force on the guide convex portion 62 is released, the part holding portion 36A is automatically restored to the retreat position via the elastic restoring force of the spring members 63.

Next, an operation for temporarily pressure contacting a TCP 5 with the glass board 2 by the temporary pressure contacting portion 14A, constituted as described above, will be described. First, in the position A shown in FIG. 11, a TCP 5 is supplied by a part supply device 38 (see FIG. 6) and is retrieved and held by the part holding portion 36A. When the part holding portion 36A reaches position B, the piston 64a of the upper cylinder 64 descends from the state shown in FIG. 12 and presses the guide convex portion 62 downward. As a result of this action, the spring members 63 are elastically expanded. While the spring members 63 are storing a restoring force and as shown in FIGS. 13 and 14, the part holding portion 36A reaches a cleaning position from the retreat position, together with the TCP 5. The brush hair 53b of the rolling brush 53, now in a rotating state, are brushed against the terminal forming region of the TCP 5. Thereby brushing off the contaminating dust attached to or fixed to the terminal forming region of the TCP 5.

Since friction is occurring between the rolling brush 53 and the TCP 5, there is a possibility of generating static electricity. However, as described above, since the brush hair 53b includes conductive fiber, the generation of static electricity can be controlled. In addition, since the area of the friction between the rolling brush 53 and the TCP 5 is injected with ionized compressed air by the ionizer 51, the generation of static electricity resulting from the friction is controlled even further. By controlling the generation of static electricity in this way, contaminating dust, once brushed away from the TCP 5, does not readily adhere again to the TCP 5 or to the rolling brush 53. Therefore, a reliable removal of dust can be performed. Further, as static electricity is not readily generated, a static electric breakdown of the TCP 5 can be prevented.

When the cleaning is completed, the piston 64a of the cylinder 64 is elevated. The elastic restoring force of the spring members 63 then elevate the part holding portion 36A to the retreat position, separating the rolling brush 53 from the TCP 5. When the part holding portion 36A reaches position C, temporary pressure contacting of the TCP 5 with the liquid crystal cell 1 is performed. At position C, although not illustrated, the upper part of the part holding portion 36A is provided with a cylinder similar to cylinder 64 used at position B. Via this cylinder, the part holding portion 36A is pressed downward from the retreat position. At the same time, by releasing the retrieved and held state of the TCP 5, the TCP 5 is temporarily pressure contacted with the anisotropic conductive member 4 attached to the liquid crystal cell 1. After which, the part holding portion 36A is supplied with another TCP 5 at position A in order to repeat the process through position D.

In this way, TCP 5's can be temporarily pressure contacted with the liquid crystal cell 1 in a condition in which contaminating dust is reliably removed by cleaning. Therefore, compared to the configuration that includes an inspection device that inspects the TCP 5 and a contaminated TCP 5 with dust attached is discarded, a shortening of the cycle time may be achieved. In addition, since the TCP 5 is not discarded, a lower cost may also be achieved.

Accompanying a repeated cleaning operation of TCP 5's performed in this way, there may develop a situation in which wear and abrasion are inevitably generated in the brush hair 53b of the rolling brush 53. To cope with the occurrence of this situation, in the present embodiment the height position of the rolling brush 53 is adjustable. A jig 65, used for adjustment, and an adjusting method will be described below.

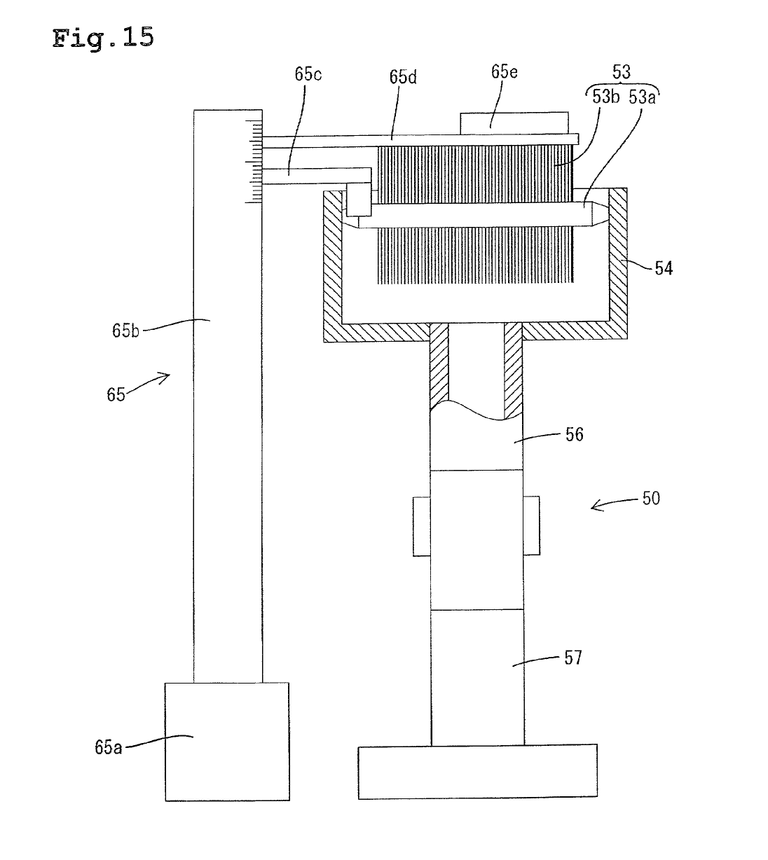

This jig 65, as shown in FIG. 15, comprises a ground base 65a, a shaft portion 65b rising from the ground base 65a, a rotational shaft index portion 65c mounted so as to be vertically movable in order to contact the shaft portion 65b, and a hair top index portion 65d. The shaft portion 65b is provided with a scale showing the height positions of both index portions 65c and 65d. The hair top index portion 65d is provided with a pressure sensor 65e so that the pressure can be detected on the undersurface of the hair top index portion 65d.

The positioning method of the rolling brush 53 will be described next. Initially, the position of the rotational shaft 53a is measured by the rotational shaft index portion 65c in the jig 65. In addition, the position of the hair top of the brush hair 53b is measured by the hair top index portion 65d. In this way, the amount of wearing evident for the brush hair 53b can be determined by comparing the results to the case where the brush hair 53b is unused. During measurement, since the position of the hair top of the brush hair 53b can be accurately measured via the pressure sensor 65e, the positioning of the rolling brush 53, described next, can be performed with a high degree of accuracy.

When the measurement by the jig 65 is completed, the positioning of the rolling brush 53 is then performed. By advancing a positioning bolt 60, as shown in FIG. 16, the support member 56 is pressed upward (i.e., a direction approaching the TCP 5) from the base portion 57, together with the rolling brush 53 and the cleaning case 54. When the support member 56 is elevated to a sufficient height to compensate for the wearing out of the brush hair 53b, the advancement of the positioning bolt 60 is stopped. In this way, the position of the hair top of the worn out brush hair 53b is disposed at approximately the same level where unused brush hair 53b would be normally. Therefore, the terminal forming portions of a TCP 5 can be reliably cleaned by the repositioned brush hair 53b when the two contact one another in the cleaning position.

As another positioning method, for example, the hair top index portion 65d in the jig 65 is disposed at a position in which the hair top of the brush hair 53b would reliably contact the TCP 5 in the cleaning position. The positioning bolt 60 elevates the rolling brush 53 until the brush is detected by the pressure sensor 65e. At this point, the elevation of the brush may be considered completed.

The present invention is not to be limited to the above described configurations with reference to the drawings. For example, the following configurations are also included within the scope of the present invention. Moreover, other than the configurations described below, various modifications can be implemented without departing from the technical teachings and subject matter of the invention.

The invention can be applied not only to a situation where a TCP is temporarily pressure contacted with a liquid crystal cell, but also to the case where electronic parts other than a TCP, for example, a semiconductor device and the like, are mounted on a circuit board instead of a liquid crystal cell. To specifically enumerate some of the electronic parts other than the TCP that are available, there are an SOF (System On Film), which mounts the parts such as an IC, and LSI and is much more enhanced in wiring density than the TCP, and COF (Chip On Film). Also available are an FPC (flexible Printed Circuit) which mounts a condenser, a resistor and the like on the film in which a conductive path is printed, and an FPC, which does not mount a condenser, a resistor and the like on the film, but only has an electrical connecting function. The case where these electronic parts are mounted on the liquid crystal cell is also included in the present invention. Further, the case where the above described various electronic parts are mounted on systems other than a liquid crystal cell is also included in the present invention.

Above, the cleaning device is described in relation to the liquid crystal display device, but the cleaning device is not limited to liquid crystal display devices. The cleaning device may also be applicable to the display device of other flat displays such as a plasma display and the like, wherein the same effect can be obtained.

While a CCD camera can be used as an inspection device, a laser beam transmitter/receiver may be used in place of the CCD camera. That is, the laser beam is irradiated at the terminal forming portion of a TCP 5, while the TCP 5 is stopped at a position such as position B. The laser beam transmitter/receiver for receiving the reflected light is disposed, and this laser beam transmitter/receiver may be relatively moved for the TCP, so that the laser beam scans the terminal portion of the TCP. Based upon a change in the amount of light reflecting from the terminal portion by this scan, the system can determine whether or not contaminating dust of more than a predetermined size is attached to the terminal portion of the TCP.

Even though conductive fibers are used for the brush hair material of the brush or the rolling brush in addition to the charge elimination performed by the ionizer as described, the case where, for example, either one or both of the ionizer being omitted or the brush hair comprising non conductive fiber is included within the scope of the invention.

While it is disclosed that the injection direction of the gas by both the ionizer and the nozzle member is in a direction opposing the ingress direction of the board, with regard to either one or both of the ionizer and the nozzle member, the injection direction of the gas may be the same direction as the ingress direction of the board. Further, the shape of the injection orifice of the nozzle member may be changed arbitrarily to suit specific needs. In addition, the case where the nozzle member is omitted is also included within the teachings of the present invention.

While it is described that the part holding portion is moved up and down between the waiting position and the cleaning position, a configuration where the rolling brush side is moved up and down is also included in the subject matter of the invention.

While it is described that the rolling brush is used as the cleaning device of the TCP, a stationary brush, i.e., not rotating, may be used. Further, a brush linearly moving along the surface of the TCP may be used. Similarly, with regard to the brush used in the terminal cleaning portion, a brush linearly moving along the board surface of the glass board and/or a rolling brush may be used.

While it is described that the insertion hole of the brush holding member is in the shape of an elongated hole or slot, conversely the insertion holes on the bracket side may be in the shape of an elongated hole or slot.

While it is described that the positioning of the brush is performed by moving the bolt along the elongated insertion hole, a positioning bolt threadably engaged with the brush holding member can be advanced and retreated so that the brush bracket may be moved up and down. Similarly, this configuration may be the same as the structure shown in the FIGS. 8 through 10.

The present invention is suitable for manufacturing a flat display panel of a liquid crystal display device and the like.

What is claimed:

1. A mounting apparatus for mounting electronic parts comprising:
a part conveying device in which a plurality of part holding portions are integrally provided along a peripheral direction at a predetermined interval, wherein the plurality of part holding portions are intermittently driven in a peripheral direction;
a part supply portion for supplying an electronic part to each part holding portion of said part conveying device intermittently driven; and
an inspection device for inspecting whether or not dust is attached to the electronic parts supplied and held by said part holding portion at a position where said part holding portion stops by the intermittent driving of said part conveying device.

2. The mounting apparatus according to claim 1, further comprising a control device for collecting data from the inspection device and making a determination which parts meet a predetermined quality standard.

3. Mounting equipment for mounting electronic parts on an edge portion of a board in which terminals are formed, comprising:
a part conveying device in which a plurality of part holding portions are integrally provided along a peripheral direction at predetermined intervals and these part holding portions are intermittently driven in a peripheral direction;
a part supplying portion for supplying said electronic parts successively to each part holding portion of said part conveying device intermittently driven;
a brush having brush hair that includes conductive fiber, the brush for removing dust attached to the electronic parts by the brush hair brushing connection regions with said terminals of said electronic parts at a stage prior to mounting said electronic parts supplied and held by said part holding portion on the edge portion of said board; and
a discharge device for discharging the dust removed by said brush.

4. Mounting equipment of mounting electronic parts on an edge portion of a board in which terminals are formed, comprising:
a part conveying device in which a plurality of part holding portions are integrally provided along a peripheral direction at predetermined intervals and these part holding portions are intermittently driven in the peripheral direction;
a part supplying portion for supplying said electronic parts successively to each part holding portion of said part conveying device intermittently driven;
a brush capable of removing the dust attached to the electronic parts by brushing the connection regions with said terminals of said electronic parts at a stage prior to mounting said electronic parts supplied and held by said part holding portion on the edge portion of said board;
an ion injection device for injecting an ionized gas toward the portion to contact at least the connection regions of said electronic parts of the brush; and
a discharge device for discharging the gas injected from the ion injection means toward said brush.

5. The mounting equipment of the electronic parts according to claim 4, comprising a brush positioning device capable of adjusting the position of said brush in a direction in and out of contact with said electronic parts.

6. The mounting equipment of the electronic parts according to claim 5, wherein a brush position detecting device capable of detecting the top end position of the brush hair is detachably attachably provided, and wherein the brush position detecting device comprises a pressure sensor capable of detecting the abutting of the top end of the brush hair against the sensor.
